(19) United States
(12) Patent Application Publication
(10) Pub. No.: US 2019/0229713 A1
(43) Pub. Date: Jul. 25, 2019

(54) TEMPERATURE COMPENSATION CIRCUIT FOR A RING OSCILLATOR

(71) Applicant: TEXAS INSTRUMENTS INCORPORATED, Dallas, TX (US)

(72) Inventor: Kannan KRISHNA, Dallas, TX (US)

(21) Appl. No.: 15/994,387

(22) Filed: May 31, 2018

Related U.S. Application Data
(60) Provisional application No. 62/621,857, filed on Jan. 25, 2018.

(51) Int. Cl. H03K 3/03; H03K 3/011; H03B 5/04

(52) U.S. Cl. CPC H03K 3/0315; H03K 2005/00039; H03B 5/04; H03K 3/011

(57) ABSTRACT

A temperature-compensated ring oscillator circuit includes a plurality of series-coupled inverters in a ring configuration and a plurality of capacitors. Each capacitor couples to an output of a corresponding inverter. A first transistor is included that comprises a first control input and first and second current terminals. The second current terminal couples to the power supply terminal of each inverter. A second transistor is included that comprises a second control input and third and fourth current terminals. A resistor couples to the fourth current terminal of the second transistor at a first node. An amplifier includes a first amplifier input, a second amplifier input, and an amplifier output. The amplifier output couples to the first and second control inputs. The first amplifier input couples to the second current terminal of the first transistor and the second amplifier input couples to the first node.

### RELATED APPLICATIONS

This application claims priority to U.S. Provisional Application No. 62/621,857, filed Jan. 25, 2018, which is hereby incorporated by reference.

### BACKGROUND

A variety of circuits and devices are available to generate a clock signal. A ring oscillator is one such circuit. A ring oscillator typically includes an odd number of inverters connected in series in a ring configuration. Because there is an odd number of inverters, the output signal from each inverter toggles between logic states. The output of any of the inverters therefore can be used as a dock signal. The frequency of the dock signal depends on the number of inverters in the ring. The frequency of the dock signal also varies based on temperature. For some applications of the use of the ring oscillators, temperature effects on the clock frequency is not significant. However, for other applications, frequency dependence on temperature can be a problem.

### SUMMARY

A temperature-compensated ring oscillator circuit includes a plurality of series-coupled inverters in a ring configuration and a plurality of capacitors. Each capacitor couples to an output of a corresponding inverter. A first transistor is included that comprises a first control input and first and second current terminals. The second current terminal couples to the power supply terminal of each inverter. A second transistor is included that comprises a second control input and third and fourth current terminals. A resistor couples to the fourth current terminal of the second transistor at a first node. An amplifier includes a first amplifier input, a second amplifier input, and an amplifier output. The amplifier output couples to the first and second control inputs. The first amplifier input couples to the second current terminal of the first transistor and the second amplifier input couples to the first node.

### BRIEF DESCRIPTION OF THE DRAWINGS

For a detailed description of various examples, reference will now be made to the accompanying drawings in which:

FIG. 1 illustrates a temperature-compensated ring oscillator circuit in accordance with an example.

### DETAILED DESCRIPTION

A temperature compensation circuit for a ring oscillator is described herein. In one example, the temperature compensation circuit includes a pair of feedback loops coupled to the ring oscillator. The feedback loops represent a self-biased circuit. The circuit is self-biased based on temperature and causes the supply current to the ring oscillator to automatically change to maintain a constant frequency level. A resistor (with a resistance R) and multiple capacitors (having the same capacitance C) are included in the temperature compensation circuit. The clock frequency of the ring oscillator is proportional to 1/RC. The resistor and capacitors are selected to have low temperature coefficients and thus, the clock frequency of the ring oscillator has little, if any, dependence on temperature.

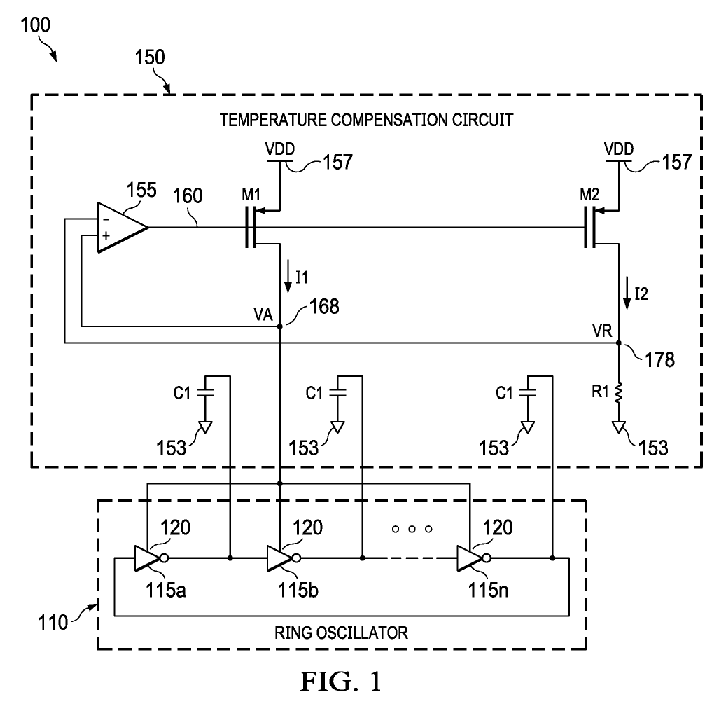

FIG. 1 provides an example of a temperature-compensated ring oscillator circuit 100. The example temperature-compensated ring oscillator circuit 100 of FIG. 1 includes a ring oscillator 110 coupled to a temperature compensation circuit 150. The ring oscillator 110 comprises multiple inverters 115a, 115b, . . . , 115n (collectively inverters 115) and/or other types of electrical components. In some examples, there is an odd number of inverters 115. The inverters 115 are serially-connected to each other in a ring configuration as shown. That is, the output of one inverter 115 is connected to the input of the next inverter in the ring. The output signal from any one of the inverters 115 is a periodic signal (a clock signal) and thus any of the inverters' outputs can be used as the output signal from the ring oscillator. The frequency of oscillation is inversely proportional to the number of inverters 115 in the ring, that is, the greater is the number of inverters 115 in the ring, the smaller is the oscillation frequency of the output signal from any of the inverters. Each inverter 115 includes a power supply terminal 120.

A capacitor C1 is connected to the connection point between each connected pair of inverters. One terminal of each capacitor C1 connects to the output of one inverter 115 and to the input of the next serially-connected inverter, and the other terminal of the capacitor connects to a power node 153 (e.g., ground).

The temperature compensation circuit 150 comprises an amplifier 155, a transistor M1, a second transistor M2, and a resistor R1. Each transistor M1 and M2 includes a control input and a pair of current terminals. In the example of FIGS. 1, M1 and M2 are implemented as p-type metal oxide semiconductor field effect transistors (PMOS). As such, the control input is the gate of the transistors and the current terminals comprise the source and drain of the transistor. In other implementations, either or both of M1 and M2 can be implemented as n-type metal oxide semiconductor field effect transistors (NMOS), as bipolar junction transistors (n-type or p-type), or as other types of transistors. In the example of FIG. 1, the sources of M1 and M2 are connected to a power supply node 157 (e.g., VDD). The amplifier 155 includes an inverting (negative) input and a non-inverting (positive) input. The drain of M1 is connected to the positive input of amplifier 155, and the drain of M2 is connected to the negative input of amplifier 155. The drain of M1 is also connected to the power supply terminal 120 of each of the inverters 115. As such, current I1 conducted through M1 provides the power supply current to each of the inverters 115. The drain of M2 connects to one terminal of resistor R1, and the other terminal of resistor R1 is connected to the power supply node 153 (e.g., ground).

As noted above, the frequency of the output signal from any of the inverters 115 is inversely proportional to the number of inverters 115 in the ring configuration. The number of inverters 115 in the ring configuration is designated as K2. The current I1 is the through M1 and represents the power supply current to the collection of inverters 115 as shown in FIG. 1. The current through M2 is designated as I2. M1 and M2 are current source device whose current is, at least in part, a function of the size of each transistor. In one example, M2 is smaller (in terms of channel length and width) than M1 and thus I2 is smaller than I1. The ratio of I2 to I1 is designated herein as K1 (e.g., K1=I2/I1). In addition to being inversely proportional to K2, the frequency of the output signal from any of the inverters 115 is inversely proportional to the product of K1, K2, C1 (capacitance value of capacitor C1) and R1 (resistance value of resistor R1). That is,

$$Frequency ∝ \frac{1}{K 1 * K 2 * C 1 * R 1} \qquad ( 1 )$$

The capacitors C1 and the resistor R1 are chosen to have a relatively low temperature variation. That is, the capacitance of C1 and the resistance of R1 do not vary much with temperature. In one example, R1 has a temperature coefficient of less than 100 parts per million per degree centigrade. In other example, R1 has a temperature coefficient of less than 40 parts per million per degree centigrade. Similarly, each capacitor C1 has a temperature coefficient of less than 100 parts per million per degree centigrade or less than 40 parts per million per degree centigrade. Further, in other examples, the product of R1 and C1 varies by less than 40 (or 100) parts per million per degree centigrade. In some implementations, each capacitor C1 is a metal-metal capacitor, a poly-poly capacitor, or another type of low temperature coefficient capacitor. Resistor R1 may be implemented as a thin film resistor or other type of low temperature coefficient resistor.

The temperature compensation circuit 150 includes two feedback loops—one including M1 and the other including M2—that operate in parallel. The amplifier 155 produces an output signal 160 that adjusts the gate to source voltage on M1 and M2 so as to regulate the voltage on node 168 (supply voltage to the inverters 115, designated as VA) to be equal to the voltage on node 178 (voltage across resistor R1, designated as VR). If the temperature were to drift upward, without temperature compensation, the frequency of a ring oscillator would decrease as, for a constant input current or voltage, the delay through each inverter would increase. Reciprocally, if the temperature were to drift downward, without temperature compensation, the frequency of a ring oscillator would increase as, for a constant input current or voltage, the delay through each inverter would decrease. As the temperature increases, voltage VA on node 168 decreases with the frequency. A decreasing voltage VA causes the amplifier 155 to generate a lower voltage as its output signal 160. In response to a smaller output signal 160, the gate-to-source voltage of M1 becomes larger thereby causing M1 to be driven more strongly. With M1 driven more strongly, I1 increases thereby providing more current and a higher supply voltage to the inverters 115. The decreasing output signal 160 from amplifier 155 also drives M2 more strongly thereby increasing I2. The change (increase) in supply current to the inverters 115 continues until VA is approximately equal to VR. The feedback loops including M1 and M2 regulate the supply current and voltage to the inverters 115 in order to maintain VA approximately equal to VR. The increasing temperature tends to cause the frequency to decrease, but the temperature compensation circuit 150 responds by increasing I1 to the inverters thereby counteracting the effect of the increasing temperature on frequency.

The opposite effect occurs if the temperature decreases. As the temperature decreases, the frequency of the ring oscillator 110 increases as does the voltage VA. An increasing VA causes the amplifier 155 to generate a higher voltage for its output signal 160. In response to a higher output signal 160, the gate-to-source voltage of M1 becomes smaller thereby causing M1 to be driven more weakly. With M1 driven more weakly, I1 decreases thereby providing less current and a lower supply voltage to the inverters 115. The decreasing output signal 160 from amplifier 155 also drives M2 more weakly thereby causing a decrease in I2. The change in supply current to the inverters 115 continues until VA is approximately equal to VR. The decreasing temperature tends to cause the frequency to increase, but the temperature compensation circuit 150 responds by decreasing I1 to the inverters thereby counteracting the effect of the decreasing temperature on frequency.

The opposite effect occurs if the temperature decreases. As the temperature decreases, the frequency increases as noted above. From Eq. (2), I2 will increase as the frequency increases. Thus, I2 will increase with decreasing temperature. As I2 increases, VR (voltage across R1) also increases. An increasing VR causes the amplifier 155 to generate a lower voltage on output signal 160. In response to a lower output signal 160, the gate-to-source voltage of M1 becomes larger thereby causing M1 to be driven more weakly. With M1 driven more weakly, I1 decreases thereby providing less current and a lower supply voltage to the inverters 115. The decreasing output signal 160 from amplifier 155 also drives M2 more weakly thereby decreasing I2. The change in supply current to the inverters 115 continues until VA is approximately equal to VR. The decreasing temperature tends to cause the frequency to increase, but the temperature compensation circuit 150 responds by decreasing I1 to the inverters thereby counteracting the effect of the decreasing temperature on frequency.

In this description, the term “couple” or “couples” means either an indirect or direct wired or wireless connection. Thus, if a first device couples to a second device, that connection may be through a direct connection or through an indirect connection via other devices and connections. The recitation “based on” means “based at least in part on.” Therefore, if X is based on Y, X may be a function of Y and any number of other factors. Modifications are possible in the described embodiments, and other embodiments are possible as well, and within the scope of the claims.

What is claimed is:

1. A temperature-compensated ring oscillator circuit, comprising:
a plurality of series-coupled inverters in a ring configuration, each inverter having a power supply terminal and the output of inverter coupled to an input of the next series-coupled inverter in the ring configuration;
a plurality of capacitors, each capacitor coupled to an output of a corresponding inverter;
a first transistor comprising a first control input and first and second current terminals, the second current terminal coupled to the power supply terminal of each inverter;
a second transistor comprising a second control input and third and fourth current terminals;
a resistor coupled to the fourth current terminal of the second transistor at a first node; and
an amplifier including a first amplifier input, a second amplifier input, and an amplifier output, the amplifier output coupled to the first and second control inputs, the first amplifier input coupled to the second current terminal of the first transistor, and the second amplifier input coupled to the first node.

2. The temperature-compensated ring oscillator circuit of claim 1, wherein the resistor is a resistor with a temperature coefficient of less than 100 parts per million per degree centigrade.

3. The temperature-compensated ring oscillator circuit of claim 1, wherein the resistor is a resistor with a temperature coefficient of less than 40 parts per million per degree centigrade.

4. The temperature-compensated ring oscillator circuit of claim 1, wherein each capacitor is a capacitor with a temperature coefficient less than 100 parts per million per degree centigrade.

5. The temperature-compensated ring oscillator circuit of claim 1, wherein each capacitor is a capacitor with a temperature coefficient less than 40 parts per million per degree centigrade.

6. The temperature-compensated ring oscillator circuit of claim 1, wherein a product of a resistance value of the resistance and a capacitance value of each capacitor varies by less than 40 parts per million per degree centigrade.

7. The temperature-compensated ring oscillator circuit of claim 1, wherein a size of the second transistor is smaller than a size of the first transistor.

8. The temperature-compensated ring oscillator circuit of claim 1, wherein the first transistor comprises a p-type metal oxide semiconductor field effect transistor in which the first current terminal is a source that is coupled to a supply voltage node, and the second transistor comprises a p-type metal oxide semiconductor field effect transistor in which the third current terminal is a source that is coupled to the supply voltage node.

9. A temperature compensation circuit, comprising:
a plurality of capacitors, each capacitor to couple to an output of one inverter of a series-coupled ring of inverters;
a first transistor comprising a first control input and first and second current terminals, the second current terminal to couple to a power supply terminal of each inverter;
a second transistor comprising a second control input and third and fourth current terminals;
a resistor coupled to the fourth current terminal of the second transistor at a first node; and
an amplifier including a first amplifier input, a second amplifier input, and an amplifier output, the amplifier output coupled to the first and second control inputs, the first amplifier input coupled to the second current terminal of the first transistor, and the second amplifier input coupled to the first node.

10. The temperature compensation circuit of claim 9, wherein the resistor is a resistor with a temperature coefficient of less than 100 parts per million per degree centigrade.

11. The temperature compensation circuit of claim 9, wherein the resistor is a resistor with a temperature coefficient of less than 40 parts per million per degree centigrade.

12. The temperature compensation circuit of claim 9, wherein each capacitor is a capacitor with a temperature coefficient less than 100 parts per million per degree centigrade.

13. The temperature compensation circuit of claim 9, wherein each capacitor is a capacitor with a temperature coefficient less than 40 parts per million per degree centigrade.

14. The temperature compensation circuit of claim 9, wherein a product of a resistance value of the resistance and a capacitance value of each capacitor varies by less than 40 parts per million per degree centigrade.

15. The temperature compensation circuit of claim 1, wherein a size of the second transistor is smaller than a size of the first transistor.

16. The temperature compensation circuit of claim 1, wherein the first transistor comprises a p-type metal oxide semiconductor field effect transistor in which the first current terminal is a source that is coupled to a supply voltage node, and the second transistor comprises a p-type metal oxide semiconductor field effect transistor in which the third current terminal is a source that is coupled to the supply voltage node.

17. A temperature-compensated ring oscillator circuit, comprising:
a ring oscillator;
a plurality of capacitors coupled to the ring oscillator;
a first transistor comprising a first control input and first and second current terminals, the second current terminal coupled to a power supply terminal of electrical components of the ring oscillator;
a second transistor comprising a second control input and third and fourth current terminals;
a resistor coupled to the fourth current terminal of the second transistor at a first node; and
an amplifier including a first amplifier input, a second amplifier input, and an amplifier output, the amplifier output coupled to the first and second control inputs, the first amplifier input coupled to the second current terminal of the first transistor, and the second amplifier input coupled to the first node.

18. The temperature-compensated ring oscillator circuit of claim 17, wherein the ring oscillator comprises a plurality of inverters.

19. The temperature-compensated ring oscillator circuit of claim 17, wherein a product of a resistance value of the resistance and a capacitance value of each capacitor varies by less than 40 parts per million per degree centigrade.

20. The temperature-compensated ring oscillator circuit of claim 17, wherein a size of the second transistor is smaller than a size of the first transistor.
